(19) United States
(12) Patent Application Publication
(10) Pub. No.: US 2015/0248067 A1
(43) Pub. Date: Sep. 3, 2015

(54) DETERMINATION METHOD, EXPOSURE APPARATUS, EXPOSURE SYSTEM, METHOD OF MANUFACTURING ARTICLE, AND STORAGE MEDIUM

(71) Applicant: CANON KABUSHIKI KAISHA, Tokyo (JP)

(72) Inventor: Yoshihito Tada, Utsunomiya-shi (JP)

(21) Appl. No.: 14/630,858

(22) Filed: Feb. 25, 2015

(30) Foreign Application Priority Data
Mar. 3, 2014 (JP) 2014-041049

(51) Int. Cl. G03F 7/20

(52) U.S. Cl. CPC G03F 7/70483

(57) ABSTRACT

The present invention provides a determination method of determining an order when an exposure apparatus performs a plurality of exposure processing operations sequentially, the method comprising obtaining a first standby time required until a first exposure processing out of the plurality of exposure processing operations is ready to start, obtaining a second standby time required until a second exposure processing out of the plurality of exposure processing operations is ready to start; and determining the order to perform the first exposure processing before the second exposure processing in a case where the first standby time is shorter than the second standby time, and to perform the first exposure processing after the second exposure processing in a case where the first standby time is longer than the second standby time.

### BACKGROUND OF THE INVENTION

1. Field of the Invention

The present invention relates to a determination method of determining an order of a plurality of exposure processing operations, an exposure apparatus, an exposure system, a method of manufacturing an article, and a storage medium.

2. Description of the Related Art

Along with the micropatterning of a semiconductor device or the like, an exposure apparatus which transfers the pattern of a mask (an original) onto a substrate is required to accurately transfer the pattern of the mask onto the substrate. However, when the pattern is transferred onto the substrate using a mask having a temperature difference from the internal temperature of the exposure apparatus, the mask may be deformed because of the temperature change of the mask during alignment between the mask and the substrate or exposure of the substrate, thereby causing a transfer error. To prevent this, Japanese Patent Laid-Open No. 2010-283305 proposes an exposure apparatus in which a means for performing temperature adjusting of a mask is provided and exposure processing is performed after bringing the mask temperature closer to the internal temperature of the exposure apparatus.

The exposure apparatus is required to increase a throughput. Since the means for performing temperature adjusting of the mask is provided in the exposure apparatus described in Japanese Patent Laid-Open No. 2010-283305, it is possible to make a time to bring the mask temperature closer to the internal temperature of the exposure apparatus shorter as compared to a case in which the means for performing temperature adjusting of the mask is not provided. However, Japanese Patent Laid-Open No. 2010-283305 does not describe changing the order of a plurality of exposure processing operations so as to increase the throughput when these operations are performed by using a plurality of masks.

### SUMMARY OF THE INVENTION

The present invention provides a technique advantageous in, for example, increasing a throughput when performing a plurality of exposure processing operations sequentially.

According to one aspect of the present invention, there is provided a determination method of determining an order when an exposure apparatus performs a plurality of exposure processing operations sequentially, the method comprising: obtaining a first standby time required until a first exposure processing out of the plurality of exposure processing operations is ready to start; obtaining a second standby time required until a second exposure processing out of the plurality of exposure processing operations is ready to start; and determining the order to perform the first exposure processing before the second exposure processing in a case where the first standby time is shorter than the second standby time, and to perform the first exposure processing after the second exposure processing in a case where the first standby time is longer than the second standby time, wherein a temperature of an original used for the first exposure processing falls within an allowable range until the first exposure processing is ready to start, and the time required until the temperature of the original falls within the allowable range is longer than a first conveyance time required until the original is conveyed to a first exposure position of the exposure apparatus, and longer than a second conveyance time required until a substrate which should be undergone the first exposure processing is conveyed to a second exposure position of the exposure apparatus.

Further features of the present invention will become apparent from the following description of exemplary embodiments with reference to the attached drawings.

### BRIEF DESCRIPTION OF THE DRAWINGS

FIG. 1 is a schematic diagram showing the arrangement of an exposure system according to the first embodiment;

FIG. 2 is a conceptual view showing, in time-series, processing when determining the execution order of a plurality of exposure processing operations;

FIG. 3 is a graph showing the temperature change model of a mask after the mask is loaded into an exposure apparatus;

FIG. 4A is a table showing a management table;

FIG. 4B is a flowchart showing a step of calculating a standby time;

FIG. 5 is a schematic diagram showing the arrangement of an exposure system according to the second embodiment;

FIG. 6 is a conceptual view showing, in time-series, processing when determining the execution order of a plurality of exposure processing operations; and

FIG. 7 is a block diagram showing the arrangement of an information processing apparatus.

### DESCRIPTION OF THE EMBODIMENTS

Exemplary embodiments of the present invention will be described below with reference to the accompanying drawings. Note that the same reference numerals denote the same members throughout the drawings, and a repetitive description thereof will not be given.

### First Embodiment

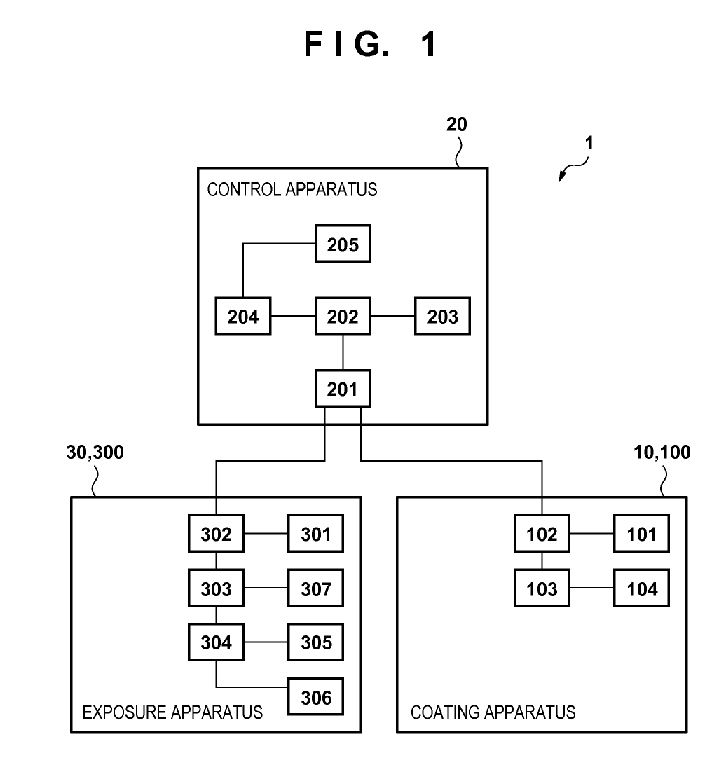

In the first embodiment, a method of determining an execution order (an order) when an exposure apparatus 30 performs a plurality of exposure processing operations sequentially in an exposure system 1 including the exposure apparatus 30, a coating apparatus 10, and a control apparatus 20 will be described. FIG. 1 is a schematic diagram showing the arrangement of the exposure system 1 according to the first embodiment. The exposure apparatus 30 performs exposure processing including processing of performing alignment between a mask (an original) and a substrate, and processing of exposing the substrate and transferring the pattern of the mask onto the substrate. A control unit 300 controls the exposure processing. The control unit 300 of the exposure apparatus 30 can include, for example, a mask management unit 301, a transceiver unit 302, an exposure processing management unit 303, a temperature prediction unit 304, a first measurement unit 305, a second measurement unit 306, and a mask conveyance management unit 307. FIG. 1 only shows the control unit 300 of the exposure apparatus 30. The coating apparatus 10 performs coating processing of coating (supplying) the substrate with a resist. A control unit 100 controls the coating processing. The control unit 100 of the coating apparatus 10 can include, for example, a carrier management unit 101, a transceiver unit 102, a coating processing management unit 103, and a history management unit 104. FIG. 1 only shows the control unit 100 of the coating apparatus 10. The control apparatus 20 determines the execution order in a case where the exposure apparatus 30 performs the plurality of exposure processing operations sequentially, and controls the exposure apparatus 30 and the coating apparatus 10. The control apparatus 20 can include a transceiver unit 201, a processing unit 202, a lot management unit 203, an adjustment unit 204, and a history management unit 205. Each of the control unit 300 of the exposure apparatus 30, the control unit 100 of the coating apparatus 10, and the control apparatus 20 can be formed from an information processing apparatus (for example, a computer) including a CPU, a memory, and the like.

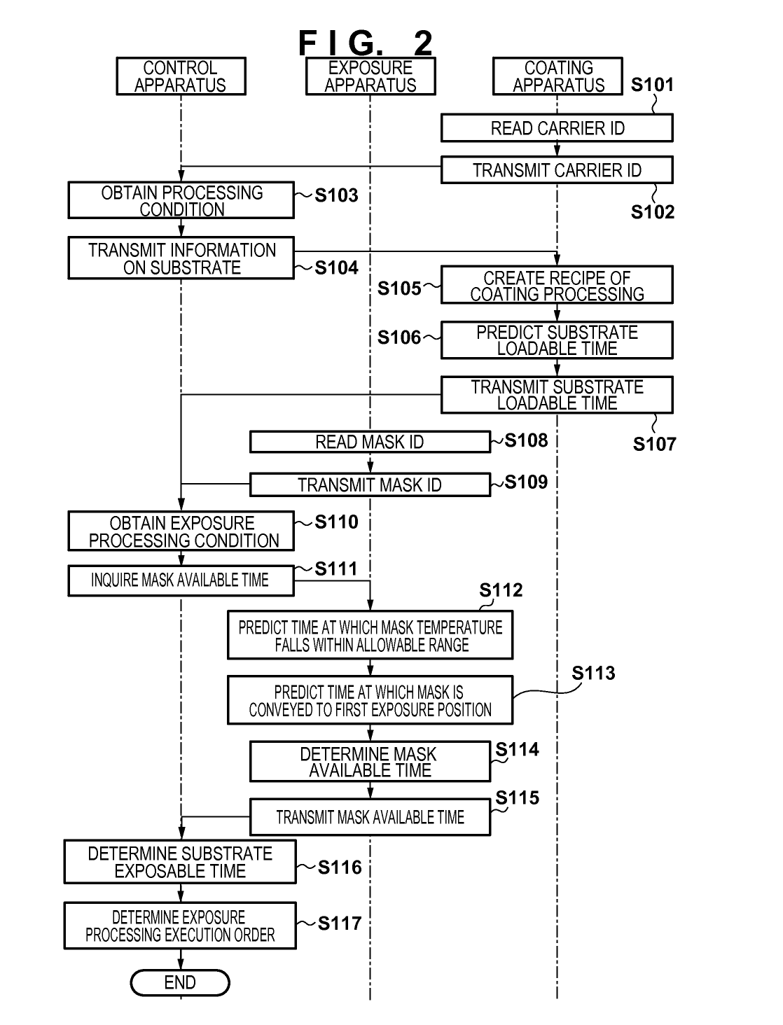

The method of determining the execution order in a case where the exposure apparatus 30 performs the plurality of exposure processing operations sequentially will now be described with reference to FIGS. 1 and 2. FIG. 2 is a conceptual view showing, in time-series, processing in the exposure apparatus 30, processing in the coating apparatus 10, and processing in the control apparatus 20, in a case where determining the execution order of the plurality of exposure processing operations.

When a carrier storing a substrate on which the coating processing and the exposure processing are planned to be performed is loaded to the coating apparatus 10, the carrier management unit 101 of the coating apparatus 10 detects the loaded carrier and reads a carrier ID (step S101). The read carrier ID is transmitted to the control apparatus 20 by the transceiver unit 102 of the coating apparatus 10, received by the transceiver unit 201 of the control apparatus 20, and then sent to the processing unit 202 (step S102). The processing unit 202 obtains the processing conditions of all the substrates stored in the carrier from the lot management unit 203 which stores information on a lot (step S103). The processing conditions can include, for example, a coating processing condition, an exposure processing condition, a mask name to be used, a lot ID, a substrate ID, and a time limit for completing the processing operations.

The processing unit 202 which has obtained the processing conditions causes the transceiver unit 201 to transmit information including the coating processing condition and a coating processing reservation of the substrate stored in the loaded carrier to the coating apparatus 10 (step S104). The transmitted information is sent to the coating processing management unit 103 of the coating apparatus 10. The coating processing management unit 103 creates the recipe of the coating processing based on the sent information and stores, as a reserved state, a job of performing the coating processing of the substrate using the created recipe (step S105). Furthermore, in a case where the substrate is coated with the resist on the coating processing condition sent from the control apparatus 20, the coating processing management unit 103 predicts a time until the substrate coated with the resist can be loaded to the exposure apparatus 30 (to be referred to as a substrate loadable time) (step S106). This prediction is performed by, for example, assuming that the job set in the reserved state has been started immediately and referring to history data on coating with the resist stored in the history management unit 104. The time predicted in the coating processing management unit 103 is converted into a predetermined date and time format in the transceiver unit 102, and then sent to the processing unit 202 via the transceiver unit 201 of the control apparatus 20 (step S107).

On the other hand, in a case where a housing case storing a mask to be used for the exposure processing is loaded to the exposure apparatus 30, the mask management unit 301 of the exposure apparatus 30 detects the loaded housing case and reads a mask ID (step S108). The read mask ID is transmitted to the control apparatus 20 by the transceiver unit 302 of the exposure apparatus 30, received by the transceiver unit 201 of the control apparatus 20, and then sent to the processing unit 202 (step S109). The processing unit 202 obtains the condition of the exposure processing performed using the mask from the lot management unit 203 which stores the information on the lot (step S110). The processing unit 202 which has obtained the exposure processing condition inquires, via the transceiver unit 201, of the exposure apparatus 30 about a time at which the temperature of the loaded mask falls within an allowable range and becomes available (to be referred to as mask available time hereinafter) (step S111). This inquiry can include, for example, information such as the allowable range of the mask temperature in a case where the mask becomes available, the presence/absence of performance of a foreign substance inspection, and the performance condition of the foreign substance inspection. The transceiver unit 302 of the exposure apparatus 30 sends the inquiry from the control apparatus 20 to the temperature prediction unit 304 via the exposure processing management unit 303.

The temperature prediction unit 304 predicts a time at which the mask temperature falls within the allowable range based on the mask temperature when the mask was loaded into the exposure apparatus and the internal temperature of the exposure apparatus 30 (step S112). The mask temperature when the mask was loaded into the exposure apparatus is measured, for example, between steps S108 and S109 by the first measurement unit 305 provided in the exposure apparatus 30. On the other hand, the internal temperature of the exposure apparatus 30 is measured by the second measurement unit 306 provided in the exposure apparatus 30. A method of predicting the time at which the mask temperature falls within the allowable range will now be described.

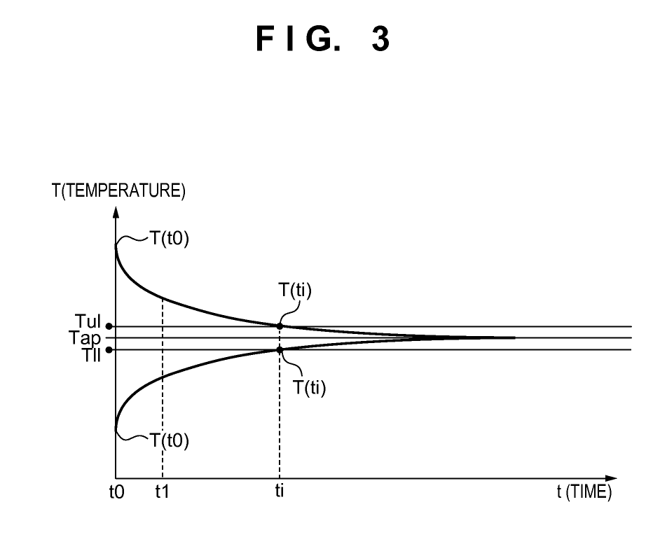

FIG. 3 is a graph showing the temperature change model of the mask after the mask is loaded into the exposure apparatus. FIG. 3 shows two cases, that is, a case in which the temperature of the mask when loaded into the exposure apparatus is higher than the internal temperature of the exposure apparatus 30, and a case in which the temperature of the mask when loaded into the exposure apparatus is lower than the internal temperature of the exposure apparatus 30. In FIG. 3, the ordinate represents a mask temperature T, and the abscissa represents a time t elapsed since the mask has been loaded into the exposure apparatus. Furthermore, Tᵤₗ is an upper limit value in the allowable range, Tₗₗ is a lower limit value in the allowable range, and t₀ is a time at which the mask is loaded into the exposure apparatus. Such a temperature change model of the mask is represented:

T(tᵢ)=Tₐₚ−(Tₐₚ−T₀)exp(−mt),m=hS/ρcV (1)

Time tᵢ at which the mask temperature falls within the allowable range can be obtained by performing a simulation or the like using equations (1). In equations (1), Tₐₚ is the internal temperature of the exposure apparatus 30, T(t₀) is the mask temperature when the mask was loaded into the exposure apparatus, T(tᵢ) is the mask temperature when the mask falls within the allowable range, and t is the time elapsed since the mask has been loaded into the exposure apparatus. In addition, h is the heat conductivity of the mask, S is the surface area of the mask, ρ is the material density of the mask, c is the specific heat of the mask, and V is the volume of the mask.

Then, the exposure processing management unit 303 inquires of the mask conveyance management unit 307 about a time at which conveyance of the mask used for exposure processing is completed. This inquiry can include information such as a time at which the mask can be conveyed to a position (first exposure position) where a mask stage holds the mask, the presence/absence of performance of the foreign substance inspection, and the performance condition of the foreign substance inspection. For example, a time at which the previous exposure processing ends can be used as the time at which the mask conveyance becomes possible. The mask conveyance management unit 307 predicts a time at which the mask is conveyed to the first exposure position in consideration of the time at which mask conveyance becomes possible and performance of the foreign substance inspection of the mask (step S113). The time at which the mask is conveyed to the first exposure position may be predicted in consideration of, for example, an idle status of a foreign substance inspection unit (not shown). The exposure processing management unit 303 determines, as the mask available time, a later time out of the time predicted in step S112 and the time predicted in step S113 (step S114). The time determined in the exposure processing management unit 303 is converted into a predetermined date and time format in the transceiver unit 302, and then sent to the processing unit 202 via the transceiver unit 201 of the control apparatus 20 (step S115). Note that steps S108 to S115 are performed after steps S101 to step S107 in FIG. 2. However, the present invention is not limited to this. Steps S108 to S115 may be performed, for example, before or in parallel to steps S101 to S107.

In a case where the substrate loadable time predicted in step S106 and the mask available time determined in step S114 are sent to the processing unit 202 of the control apparatus 20, the adjustment unit 204 of the control apparatus 20 confirms the adequacy of the execution order of the exposure processing operations in the job set in the reserved state. The adjustment unit 204 adds, to the substrate loadable time, a time (second conveyance time) from loading the substrate to the exposure apparatus to conveying the substrate to a position (second exposure position) where a substrate stage holds the substrate, and determines a time at which the substrate can be exposed (to be referred to as substrate exposable time hereinafter) (step S116). The second conveyance time can be calculated based on, for example, past conveyance times stored in the history management unit 205 of the control apparatus 20. For example, an average value of the past conveyance times except the conveyance stop owing to an conveyance error or the like can be used for calculating the second conveyance time because the calculation need not be performed with high accuracy.

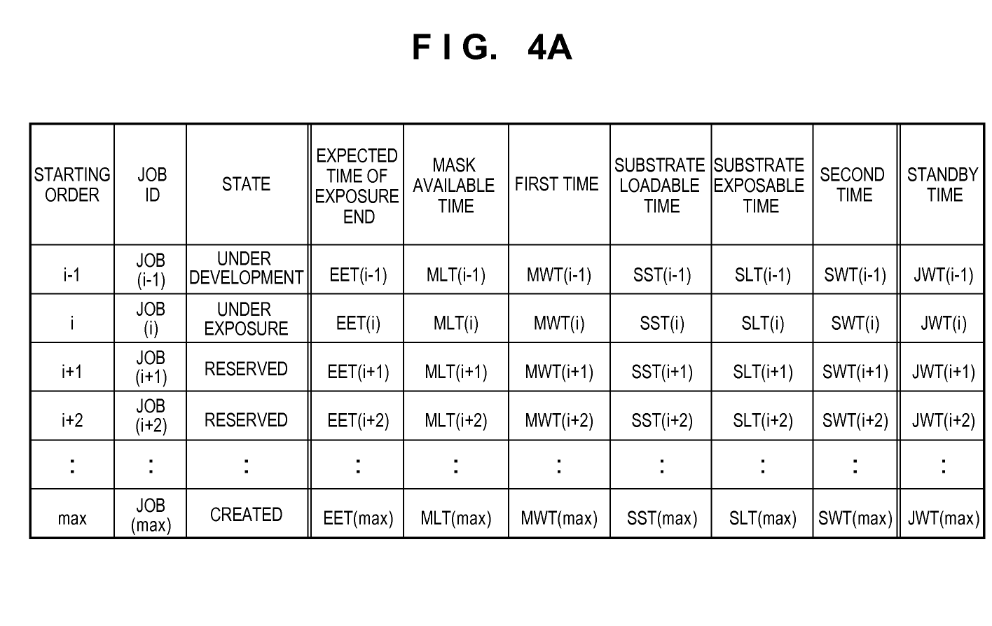

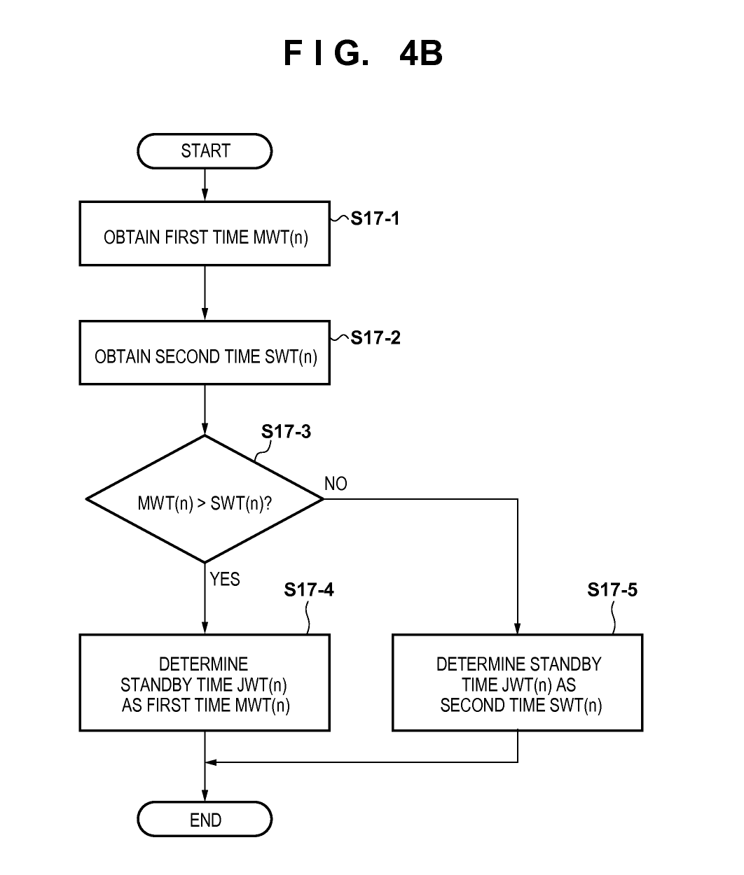

Next, the adjustment unit 204 determines, based on the mask available time and the substrate exposable time, the execution order in a case where the plurality of exposure processing operations are performed sequentially (step S117). FIG. 4A is a management table representing the execution order and the states of the plurality of exposure processing operations (jobs). The adjustment unit 204 searches the management table shown in FIG. 4A for the job under exposure, and calculates, for each of all the jobs (the jobs being reserved) which undergoes exposure processing subsequent to the job under exposure, a standby time until exposure processing is ready to start. A process of calculating the standby time will now be described with reference to FIG. 4B. FIG. 4B is a flowchart showing the process of calculating the standby time. Assume that the adjustment unit 204 of the control apparatus 20 performs respective steps in the flowchart shown in FIG. 4B.

In step S17-1, the adjustment unit 204 sets expected time EET(i) at which exposure of a job JOB(i) under exposure ends as reference time (predetermined time), and obtains a time (first time MWT(n)) from the reference time to mask available time MLT(n). The first time MWT(n) is obtained, for each job JOB(n), by MWT(n)=MLT(n)−EET(i). In step S17-2, the adjustment unit 204 obtains a time (second time SWT(n)) from the reference time to substrate exposable time SST(n). The second time SWT(n) is obtained, for each job JOB(n), by SWT(n)=SLT(n)−EET(i).

In step S17-3, the adjustment unit 204 determines whether the first time MWT(n) is longer than the second time SWT(n). If the first time MWT(n) is longer than the second time SWT(n), the process advances to step S17-4. In step S17-4, the adjustment unit 204 determines, as the first time MWT(n) obtained in step S17-1, a standby time JWT(n) required until a condition for performing exposure processing is satisfied and the exposure processing is ready to start. Note that the condition for performing exposure processing can include, as a condition, the temperature of the mask used for the exposure processing falling within the allowable range. On the other hand, if the first time MWT(n) is shorter than the second time SWT(n), the process advances to step S17-5. In step S17-5, the adjustment unit 204 determines the standby time JWT(n) as the second time SWT(n) obtained in step S17-2.

The adjustment unit 204 determines, based on the standby time JWT(n) determined in accordance with the flowchart shown in FIG. 4B, the execution order in a case where the plurality of exposure processing operations are performed sequentially. Assume that, for example, a standby time (first standby time) required until a condition (first condition) for performing exposure processing (first exposure processing) in a job JOB(i+1) is satisfied and the first exposure processing is ready to start is determined as JWT(i+1). The first condition can include, as a condition, the temperature of the mask used for the first exposure processing falling within the allowable range. Similarly, assume that a standby time (second standby time) required until a condition (second condition) for performing exposure processing (second exposure processing) in a job JOB(i+2) is satisfied and the second exposure processing is ready to start is determined as JWT(i+2). The second condition can include, as a condition, the temperature of the mask used for the second exposure processing falling within the allowable range. At this time, the adjustment unit 204 compares the first standby time JWT(i+1) with the second standby time JWT(i+2). Then, the adjustment unit 204 determines the execution order of the exposure processing operations to perform the first exposure processing before the second exposure processing in a case where the first standby time is shorter than the second standby time, and to perform the first exposure processing after the second exposure processing in a case where the first standby time is longer than the second standby time.

The adjustment unit 204 updates the management table shown in FIG. 4A by performing the above-described process on all the jobs being reserved. It is possible to reduce a time in which no exposure processing is performed in the exposure apparatus 30 by performing the plurality of exposure processing operations in accordance with the execution order in the management table thus updated. Hence, it is possible to increase the throughput of the exposure apparatus 30. An effect of increasing the throughput of the exposure apparatus 30 can typically become obvious, in particular, in a case where the time required until the mask temperature falls within the allowable range is longer than the first and the second conveyance times.

Note that the adjustment unit 204 which determines the execution order of the plurality of exposure processing operations is provided in the control apparatus 20 in the first embodiment. However, the present invention is not limited to this, and the adjustment unit 204 may be provided in, for example, the exposure apparatus 30. In this case, the execution order of the plurality of exposure processing operations can be determined in the exposure apparatus 30. If the plurality of exposure processing operations are performed in accordance with the execution order in the updated management table, coating processing of a substrate used for target exposure processing may be performed such that the substrate is loaded into the exposure apparatus immediately after exposure processing before the target exposure processing ends. That is, in the coating apparatus 10, coating processing of the substrate which undergoes the target exposure processing may be started by calculating a time required for coating processing backward from expected time at which the previous exposure processing ends. This makes it possible to further increase the throughput of the exposure apparatus 30.

Furthermore, if the standby time has not been elapsed when performing the target exposure processing, the temperature of a mask used for the target exposure processing may fall outside the allowable range even if the plurality of exposure processing operations are performed in accordance with the execution order in the updated management table. In this case, the exposure apparatus 30 can stop exposure processing by issuing a warning (an alarm). Then, the exposure apparatus 30 can restart exposure processing at a point in time when the standby time has been elapsed, that is, time at which the mask temperature falls within the allowable range. In a case where the exposure apparatus 30 is configured in this way, for example, a measurement unit which measures the temperature of a mask when the mask is arranged in the first exposure position can be provided in the exposure apparatus 30.

### Second Embodiment

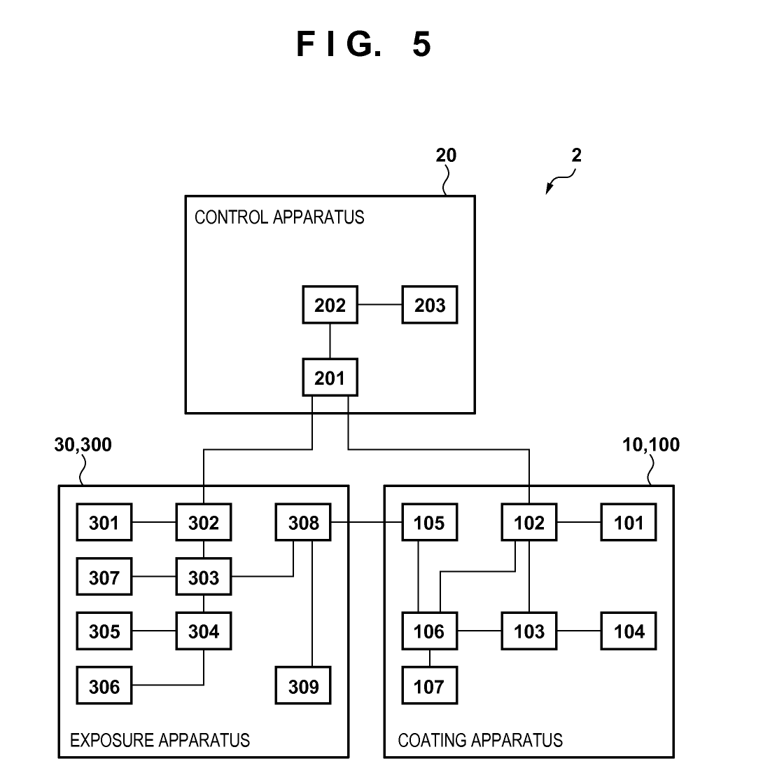

In the first embodiment, the example in which the control apparatus 20 or the exposure apparatus 30 determines the execution order of the plurality of exposure processing operations has been described. In the second embodiment, an example in which data transmission/reception is also performed between an exposure apparatus 30 and a coating apparatus 10, and the coating apparatus 10 determines the execution order of a plurality of exposure processing operations will be described. FIG. 5 is a schematic diagram showing the arrangement of an exposure system 2 according to the second embodiment. A control unit 300 of the exposure apparatus 30 can include a mask management unit 301, a transceiver unit 302, an exposure processing management unit 303, a temperature prediction unit 304, a first measurement unit 305, a second measurement unit 306, a mask conveyance management unit 307, a second transceiver unit 308, and a history management unit 309. FIG. 5 only shows the control unit 300 of the exposure apparatus 30. A control unit 100 of the coating apparatus 10 can include a carrier management unit 101, a transceiver unit 102, a coating processing management unit 103, a history management unit 104, a second transceiver unit 105, a processing unit 106, and an adjusting unit 107. FIG. 5 only shows the control unit 100 of the coating apparatus 10. Also, a control apparatus 20 can include a transceiver unit 201, a processing unit 202, and a lot management unit 203.

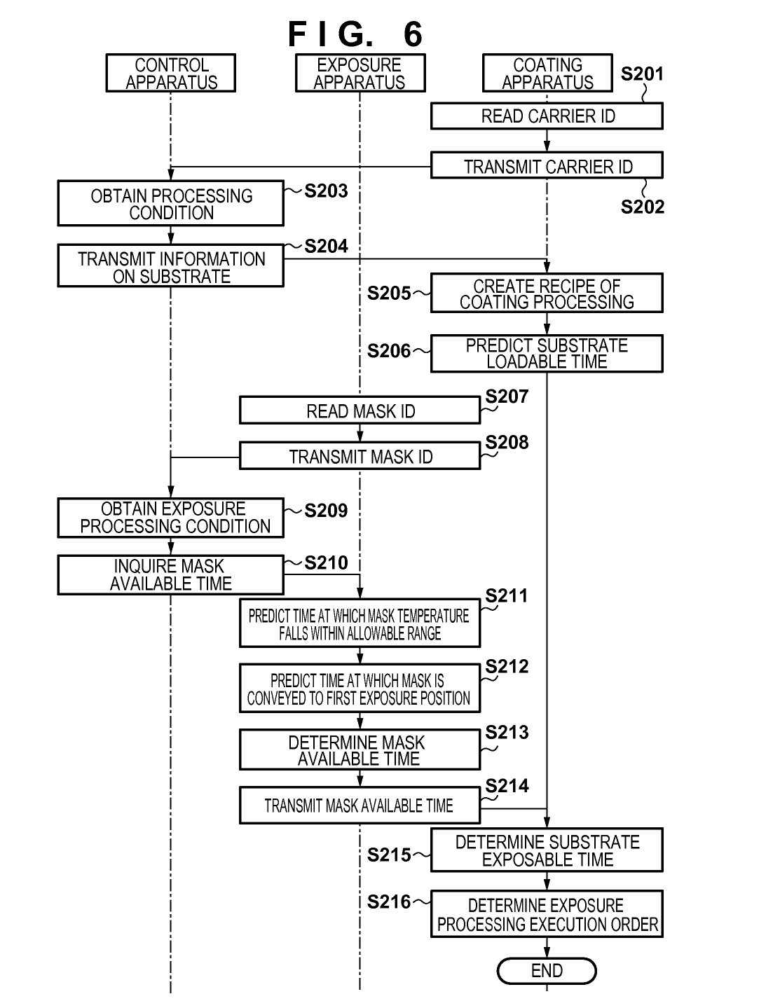

A method of determining an execution order in a case where the exposure apparatus 30 performs the plurality of exposure processing operations sequentially will now be described with reference to FIGS. 5 and 6. FIG. 6 is a conceptual view showing, in time-series, processing in the exposure apparatus 30, processing in the coating apparatus 10, and processing in the control apparatus 20, in a case where determining the execution order of the plurality of exposure processing operations. Most of the steps in the second embodiment are common to the steps in the first embodiment, and differences from the first embodiment will be described below.

In steps S201 to S206, similar processes to those in steps S101 to S106 in the conceptual view shown in FIG. 2 are performed, respectively. A time predicted in the coating processing management unit 103 is sent to the processing unit 106 of the coating apparatus 10. Also, in steps S207 to S213, similar processes to those in steps S108 to S114 in the conceptual view shown in FIG. 2 are performed, respectively. Mask available time determined in the exposure processing management unit 303 is transmitted to the coating apparatus 10 via the second transceiver unit 308 of the exposure apparatus 30, received by the second transceiver unit 105 of the coating apparatus 10, and then sent to the processing unit 106 of a coating unit (step S214). Note that steps S207 to S214 are performed after steps S201 to step S206 in FIG. 6. However, the present invention is not limited to this. Steps S207 to S214 may be performed, for example, before or in parallel to steps S201 to S206.

In a case where a substrate loadable time predicted in step S206 and the mask available time determined in step S213 are sent to the processing unit 106 of the coating apparatus 10, the adjusting unit 107 of the coating apparatus 10 confirms the adequacy of the execution order of the exposure processing operations in the job set in the reserved state. The adjusting unit 107 adds, to the substrate loadable time, the second conveyance time from loading the substrate to the exposure apparatus to conveying the substrate to a position (second exposure position) where a substrate stage holds the substrate, and determines substrate exposable time at which substrate exposure becomes possible (step S215). The second conveyance time can be calculated based on, for example, past conveyance times stored in the history management unit 309 of the exposure apparatus 30. Next, the adjustment unit 107 determines, based on the mask available time and the substrate exposable time, the execution order in a case where the plurality of exposure processing operations are performed sequentially (step S216). The process performed in step S216 is the same as that in step S117 in the conceptual view shown in FIG. 2, and a repetitive description thereof will not be given.

In the exposure system 2 according to the second embodiment, data transmission/reception is also performed between the exposure apparatus 30 and the coating apparatus 10, and the coating apparatus 10 determines the execution order of the plurality of exposure processing operations. By performing the above-described steps in such a exposure system 2, it is possible, as in the exposure system 1 according to the first embodiment, to reduce a time in which no exposure processing is performed in the exposure apparatus 30. Hence, it is possible to increase the throughput of the exposure apparatus 30. An effect of increasing the throughput of the exposure apparatus 30 can typically become obvious, in particular, in a case where a time required until a mask temperature falls within an allowable range is longer than the first and the second conveyance times. Note that the adjustment unit 107 which determines the execution order of the plurality of exposure processing operations is provided in the coating apparatus 10 in the second embodiment. However, the present invention is not limited to this, and the adjustment unit 107 may be provided in, for example, the exposure apparatus 30. That is, data transmission/reception may be performed between the exposure apparatus 30 and the coating apparatus 10, and the exposure apparatus 30 may determine the execution order of the plurality of exposure processing operations.

<Embodiment of Method of Manufacturing Article>

A method of manufacturing an article according to embodiments of the present invention is suitable for manufacturing an article, for example, an electronic device such as a semiconductor device or an element having a microstructure. The method of manufacturing the article according to this embodiment includes a step of causing an exposure apparatus to sequentially perform a plurality of exposure processing operations of exposing a substrate in an execution order determined using the above-described determination method, and a step of processing the substrate onto which the pattern has been formed by performing the exposure processing operations in the preceding step. This manufacturing method further includes other known steps (oxidation, deposition, vapor deposition, doping, planarization, etching, resist peeling, dicing, bonding, packaging, and the like). The method of manufacturing the article according to this embodiment is advantageous in at least one of the performance, the quality, the productivity, and the production cost of the article, as compared to a conventional method.

<Embodiment of Information Processing Apparatus>

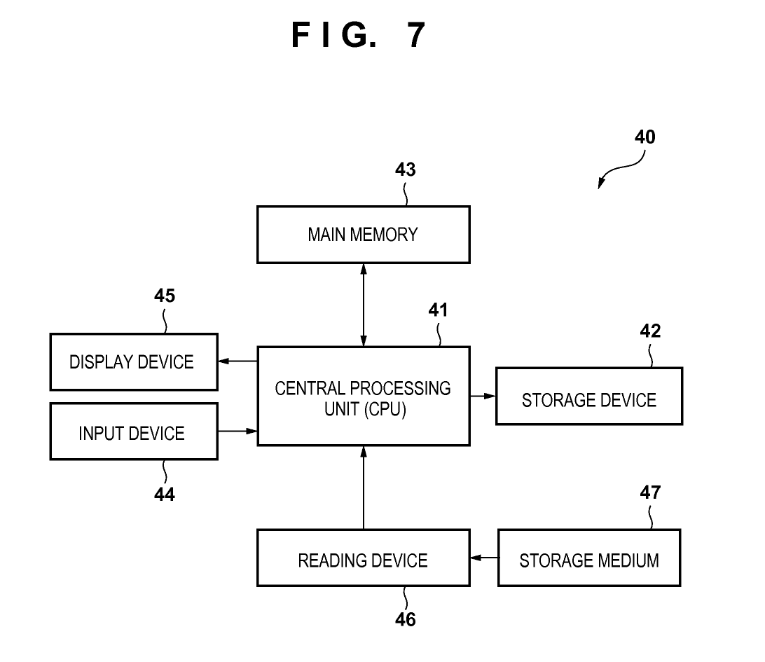

At least one of the control unit 300 of the exposure apparatus 30, the control unit 100 of the coating apparatus 10, and the control apparatus 20 in the exposure system can perform the determination methods according to the first and the second embodiments. Each of a control unit 300 of an exposure apparatus, a control unit 100 of a coating apparatus 10, and a control apparatus 20 can be formed from, for example, an information processing apparatus 40 shown in FIG. 7. FIG. 7 is a block diagram showing the arrangement of the information processing apparatus 40. The information processing apparatus 40 includes a central processing unit (CPU) 41, a storage device 42 such as a hard disk for storing a program and data, and a main memory 43. Also, the information processing apparatus 40 includes an input device 44 such as a keyboard or a mouse, a display device 45 such as a liquid crystal display, and a reading device 46 which reads out a program from a storage medium 47 such as a CD-ROM or a DVD-ROM. All of the storage device 42, the main memory 43, the input device 44, the display device 45, and the reading device 46 are connected to the central processing unit 41. In the information processing apparatus 40, the storage medium 47 which stores a program for determining an execution order in a case where the exposure apparatus performs a plurality of exposure processing operations sequentially is loaded in the reading device 46. The program is read out from the storage medium 47 by the reading device 46 and stored in the storage device 42. Note that in the information processing apparatus, the program may be stored in the storage device 42 in advance. The central processing unit 41 performs the program stored in the storage device 42, thereby performing a step of determining the execution order in a case where the exposure apparatus performs the plurality of exposure processing operations sequentially.

### Other Embodiment

Embodiment of the present invention can also be realized by a computer of a system or apparatus that reads out and performs computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and performing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and perform the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-041049 filed on Mar. 3, 2014, which is hereby incorporated by reference herein in its entirety.

What is claimed is:

1. A determination method of determining an order when an exposure apparatus performs a plurality of exposure processing operations sequentially, the method comprising:
obtaining a first standby time required until a first exposure processing out of the plurality of exposure processing operations is ready to start;
obtaining a second standby time required until a second exposure processing out of the plurality of exposure processing operations is ready to start; and
determining the order to perform the first exposure processing before the second exposure processing in a case where the first standby time is shorter than the second standby time, and to perform the first exposure processing after the second exposure processing in a case where the first standby time is longer than the second standby time,
wherein a temperature of an original used for the first exposure processing falls within an allowable range until the first exposure processing is ready to start, and
the time required until the temperature of the original falls within the allowable range is longer than a first conveyance time required until the original is conveyed to a first exposure position of the exposure apparatus, and longer than a second conveyance time required until a substrate which should be undergone the first exposure processing is conveyed to a second exposure position of the exposure apparatus.

2. The method according to claim 1, wherein each of the plurality of exposure processing operations includes processing of performing alignment between the original and the substrate.

3. The method according to claim 1, wherein the time required until the temperature of the original falls within the allowable range is predicted based on an internal temperature of the exposure apparatus and the temperature of the original when the original was loaded into the exposure apparatus.

4. The method according to claim 3, wherein letting Tₐₚ be the internal temperature, T(t₀) be the temperature of the original when the original was loaded into the exposure apparatus, T(tᵢ) be the temperature of the original when the temperature of the original fell within the allowable range, h be a heat conductivity of the original, S be a surface area of the original, ρ be a material density of the original, c be specific heat of the original, V be a volume of the original, and t be a time elapsed since the original has been loaded into the exposure apparatus, the time required until the temperature of the original falls within the allowable range is predicted based on T(tᵢ)=Tₐₚ−(Tₐₚ−T₀)exp(−mt), m=hS/ρcV.

5. The method according to claim 1, wherein the temperature of the original used for the second exposure processing falls within the allowable range until the second exposure processing is ready to start.

6. A method of manufacturing an article, the method comprising:
forming a pattern on a substrate by performing an exposure processing in accordance with an order determined by determination method;
processing the substrate, on which the pattern has been formed, to manufacture the article,
wherein the determination method determines the order when an exposure apparatus performs a plurality of exposure processing operations, and includes:
obtaining a first standby time required until a first exposure processing out of the plurality of exposure processing operations is ready to start;
obtaining a second standby time required until a second exposure processing out of the plurality of exposure processing operations is ready to start; and
determining the order to perform the first exposure processing before the second exposure processing in a case where the first standby time is shorter than the second standby time, and to perform the first exposure processing after the second exposure processing in a case where the first standby time is longer than the second standby time,
wherein a temperature of an original used for the first exposure processing falls within an allowable range until the first exposure processing is ready to start, and
the time required until the temperature of the original falls within the allowable range is longer than a first conveyance time required until the original is conveyed to a first exposure position of the exposure apparatus, and longer than a second conveyance time required until a substrate which should be undergone the first exposure processing is conveyed to a second exposure position of the exposure apparatus.

7. A non-transitory computer-readable storage medium storing a program for causing a computer in an information processing apparatus to execute a method which determines an order when an exposure apparatus performs a plurality of exposure processing operations, the method comprising:
obtaining a first standby time required until a first exposure processing out of the plurality of exposure processing operations is ready to start;
obtaining a second standby time required until a second exposure processing out of the plurality of exposure processing operations is ready to start; and
determining the order to perform the first exposure processing before the second exposure processing in a case where the first standby time is shorter than the second standby time, and to perform the first exposure processing after the second exposure processing in a case where the first standby time is longer than the second standby time,
wherein a temperature of an original used for the first exposure processing falls within an allowable range until the first exposure processing is ready to start, and
the time required until the temperature of the original falls within the allowable range is longer than a first conveyance time required until the original is conveyed to a first exposure position of the exposure apparatus, and longer than a second conveyance time required until a substrate which should be undergone the first exposure processing is conveyed to a second exposure position of the exposure apparatus.

8. An exposure apparatus which sequentially performs a plurality of exposure processing operations of exposing a substrate, the apparatus comprising:
a control unit configured to determine an order of the plurality of exposure processing operations,
wherein the control unit
obtains a first standby time required until a first exposure processing out of the plurality of exposure processing operations is ready to start,
obtains a second standby time required until a second exposure processing out of the plurality of exposure processing operations is ready to start, and
determines the order to perform the first exposure processing before the second exposure processing in a case where the first standby time is shorter than the second standby time, and to perform the first exposure processing after the second exposure processing in a case where the first standby time is longer than the second standby time,
a temperature of an original used for the first exposure processing falls within an allowable range until the first exposure processing is ready to start, and
the time required until the temperature of the original falls within the allowable range is longer than a first conveyance time required until the original is conveyed to a first exposure position of the exposure apparatus, and longer than a second conveyance time required until a substrate which should be undergone the first exposure processing is conveyed to a second exposure position of the exposure apparatus.

9. An exposure system comprising an exposure apparatus configured to sequentially perform a plurality of exposure processing operations of exposing a substrate and a control apparatus configured to determine an order of the plurality of exposure processing operations,
wherein the control apparatus
obtains a first standby time required until a first exposure processing out of the plurality of exposure processing operations is ready to start,
obtains a second standby time required until a second exposure processing out of the plurality of exposure processing operations is ready to start, and
determines the order to perform the first exposure processing before the second exposure processing in a case where the first standby time is shorter than the second standby time, and to perform the first exposure processing after the second exposure processing in a case where the first standby time is longer than the second standby time,
a temperature of an original used for the first exposure processing falls within an allowable range until the first exposure processing is ready to start, and
the time required until the temperature of the original falls within the allowable range is longer than a first conveyance time required until the original is conveyed to a first exposure position of the exposure apparatus, and longer than a second conveyance time required until a substrate which should be undergone the first exposure processing is conveyed to a second exposure position of the exposure apparatus.
